(19) United States
(12) Patent Application Publication
(10) Pub. No.: US 2025/0006723 A1
(43) Pub. Date: Jan. 2, 2025

(54) SEMICONDUCTOR DEVICE

(71) Applicant: UNITED MICROELECTRONICS CORP., Hsin-Chu City (TW)

(72) Inventor: ZHIBIAO ZHOU, Singapore (SG)

(73) Assignee: UNITED MICROELECTRONICS CORP., Hsin-Chu City (TW)

(21) Appl. No.: 18/225,706

(22) Filed: Jul. 25, 2023

(30) Foreign Application Priority Data
Jun. 28, 2023 (CN) 202310777424.8

(51) Int. Cl. H01L 27/02; H01L 29/78

(52) U.S. Cl. CPC H01L 27/0255; H01L 29/7833; H01L 29/665

(57) ABSTRACT

A semiconductor device includes a first metal-oxide semiconductor (MOS) transistor on a substrate, a pickup region adjacent to one side of the first MOS transistor, and a protection diode adjacent to another side of the first MOS transistor. Preferably, the first MOS transistor includes a first gate structure on the substrate and a first source/drain region adjacent to two sides of the first gate structure, the protection diode is electrically connected to the first gate structure, and the pickup region and the protection diode include different conductive type.

### BACKGROUND OF THE INVENTION

### 1. Field of the Invention

The invention relates to a semiconductor device, and more particularly to a protection device used for providing more stable breakdown voltage during heavy charging.

### 2. Description of the Prior Art

With the continued miniaturization of integrated circuit (IC) devices, the current trend in the sub-quarter-micron complementary metal-oxide semiconductor (CMOS) industry is to produce integrated circuits having shallower junction depths, thinner gate oxides, lightly-doped drain (LDD) structures, shallow trench isolation (STI) structures, and self-aligned silicide (salicide) processes. Nevertheless, all of these processes cause the related CMOS IC products to become more susceptible to electrostatic discharge (ESD) damage. Therefore, ESD protection circuits are built onto the chip to protect the devices and circuits of the IC against ESD damage. It is generally desired that the ESD robustness for commercial IC products be higher than 2 kV in human-body-model (HBM) ESD stress, and in order to sustain ESD overstress, devices with large dimensions need to be designed into the on-chip ESD protection circuit, and require a large total layout area on the silicon substrate.

### SUMMARY OF THE INVENTION

According to an embodiment of the present invention, a semiconductor device includes a first metal-oxide semiconductor (MOS) transistor on a substrate, a pickup region adjacent to one side of the first MOS transistor, and a protection diode adjacent to another side of the first MOS transistor. Preferably, the first MOS transistor includes a first gate structure on the substrate and a first source/drain region adjacent to two sides of the first gate structure, the protection diode is electrically connected to the first gate structure, and the pickup region and the protection diode include different conductive type.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1 illustrates a structural view of a semiconductor device according to an embodiment of the present invention.

FIG. 2 illustrates a top view of a semiconductor device according to an embodiment of the present invention.

FIG. 3 illustrates a cross-section of the semiconductor device shown in FIG. 2.

FIG. 4 illustrates a top view of the semiconductor device according to an embodiment of the present invention.

FIG. 5 illustrates a cross-section of the semiconductor device shown in FIG. 4.

FIG. 6 illustrates a structural view of a semiconductor device according to an embodiment of the present invention.

FIG. 7 illustrates a structural view of a semiconductor device according to an embodiment of the present invention.

FIG. 8 illustrates a top view of the semiconductor device according to an embodiment of the present invention.

FIG. 9 illustrates a cross-section of the semiconductor device shown in FIG. 8.

FIG. 10 illustrates a top view of the semiconductor device according to an embodiment of the present invention.

FIG. 11 illustrates a cross-section of the semiconductor device shown in FIG. 10.

### DETAILED DESCRIPTION

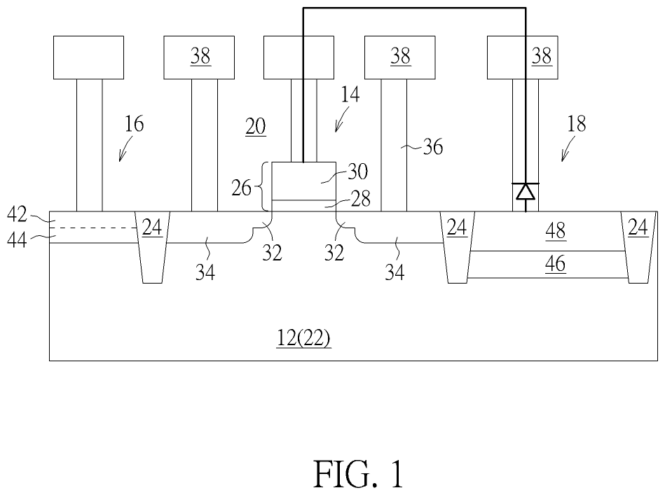

Referring to FIG. 1, FIG. 1 illustrates a structural view of a semiconductor device according to an embodiment of the present invention. As shown in FIG. 1, a substrate 12 is first provided, in which the substrate 12 is a semiconductor substrate made of semiconductor material including but not limited to for example silicon, germanium, silicon-germanium compounds, silicon carbide, or gallium arsenide. Next, at least a metal-oxide semiconductor (MOS) transistor 14 is formed on the substrate 12, a pickup region 16 is disposed on one side of the MOS transistor 14, a protection diode 18 is disposed on another side of the MOS transistor 14, and a dielectric layer such as an interlayer dielectric (ILD) layer 20 is formed to cover the MOS transistor 14. The substrate 12 further includes a well such as a p-well 22 disposed under the MOS transistor 14, the pickup region 16, and the protection diode 18 and a shallow trench isolation (STI) 24 for diving the MOS transistor, the pickup region 16, and the protection diode 18.

Specifically, planar or non-planar (such as FinFET) devices could be formed on the substrate 12, in which the MOS transistor 14 could include a gate structure 26 on the substrate 12, at least a spacer (not shown) adjacent to the gate structure 26, a lightly doped drain (LDD) 32 and a source/drain region 34 in the substrate 12 adjacent to two sides of the gate structure 26, and selective epitaxial layer and/or silicides disposed on the surface of the source/drain region 34. In this embodiment, the LDD 32 preferably includes a n-type LDD or NLDD while the source/drain region 34 includes a n+ region.

Preferably, the gate structure 26 could include a gate dielectric layer 28 and a gate electrode 30, in which the gate dielectric layer 28 preferably includes silicon oxide and the gate electrode 30 could include polysilicon or metal. It should be noted that even though the gate structure 26 includes a gate electrode 30 made of polysilicon in this embodiment, according to other embodiments of the present invention it would also be desirable to conduct a replacement metal gate (RMG) process to transform the polysilicon gate structure 26 into metal gate including work function metal layers, which is also within the scope of the present invention. Since the approach of using the RMG process to transform polysilicon gates into metal gates are well known to those skilled in the art, the details of which are not explained herein for the sake of brevity.

Preferably, the spacer could be a single spacer or a composite spacer. For instance, the spacer could further include an offset spacer (not shown) and a main spacer (not shown) and the spacer could be selected from the group consisting of SiO₂, SiN, SiON, and SiCN. The source/drain region 34 and epitaxial layer could include different dopants or different material depending on the type of transistor being fabricated. For instance, the source/drain region 34 could include p-type or n-type dopants and the epitaxial layer could include silicon germanium (SiGe), silicon carbide (SiC), or silicon phosphide (SiP).

The ILD layer 20 could be disposed on the substrate 12 to cover the MOS transistor 14, and a plurality of contact plugs 36 could be formed in the ILD layer 20 to electrically connect the source/drain region 34. Next, a metal interconnective process is conducted to form inter-metal dielectric (IMD) layer (not shown) and metal interconnections 38 in the IMD layer to electrically connect the contact plugs 36. In this embodiment, each of the contact plugs 36 and/or metal interconnections 38 could be embedded in the ILD layer 20 and/or IMD layer according to a single damascene process or dual damascene process. Preferably, each of the contact plugs 36 and/or metal interconnections 38 could further includes a barrier layer and a metal layer, in which the barrier layer could be selected from the group consisting of titanium (Ti), titanium nitride (TiN), tantalum (Ta), and tantalum nitride (TaN) and the metal layer could be selected from the group consisting of tungsten (W), copper (Cu), aluminum (Al), titanium aluminide (TiAl), and cobalt tungsten phosphide (CoWP). Since the fabrication of planar or non-planar transistor and metal interconnect structures are well known to those skilled in the art, the details of which are not explained herein for the sake of brevity.

In this embodiment, the pickup region 16 disposed on left side of the MOS transistor 14 includes at least a doped region such as a doped region 42 and a doped region 44, in which the doped regions 42, 44 and the source/drain region 34 preferably include dopants of different conductive type. For instance, the doped region 42 preferably includes a lower concentration p-type LDD or PLDD while the doped region 44 includes a higher concentration p+ region and the concentration of both regions 42, 44 is greater than the concentration of p-well 22. It should be noted that even though the pickup region 16 of this embodiment includes two doped regions 42, 44, according to other embodiment of the present invention the pickup region 16 could also be made of a single doped region such as a p+ region, which is also within the scope of the present invention.

The protection diode 18 disposed on right side of the MOS transistor 14 includes a doped region 46 disposed in the substrate 12 and another doped region 48 disposed on top of the doped region 46. Preferably, the doped region 46 underneath and the doped regions 42, 44 from the pickup region 16 includes same conductive type while the concentration of the doped region 46 is slightly higher than the concentration of the doped region 44. For instance, the doped region 46 preferably includes a p++ region. The doped region 48 above and the doped region 46 underneath however have different conductive type while the doped region 48 and the source/drain region 34 have same conductive type, in which the concentration of the doped region 48 is slightly higher than the concentration of the source/drain region 34. For instance, the doped region 48 preferably includes a n++ region.

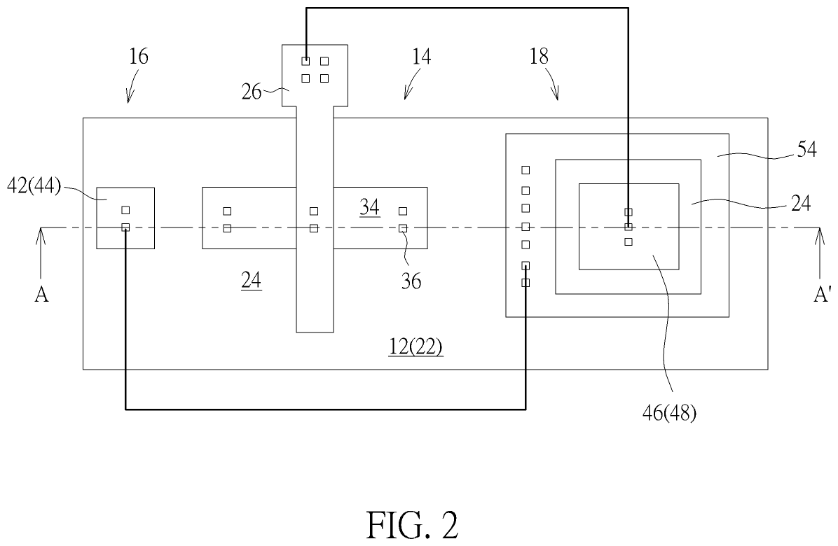

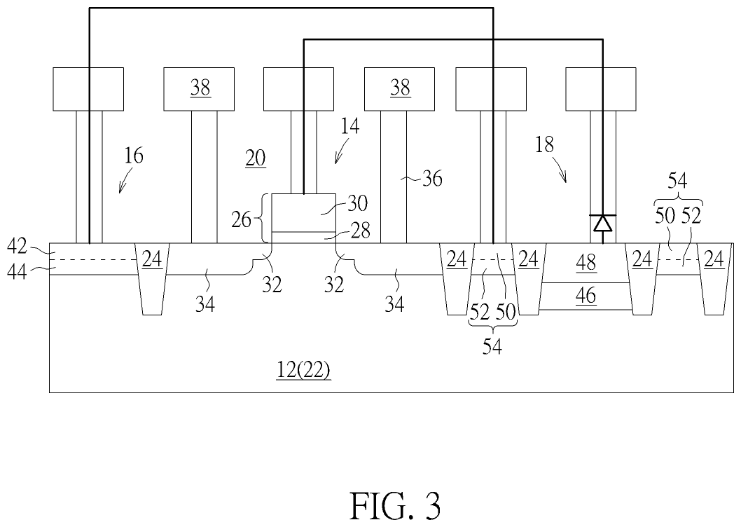

Referring to FIGS. 2-3, FIGS. 2-3 illustrate structural views of a semiconductor device according to an embodiment of the present invention, in which FIG. 2 illustrates a top view of the semiconductor device and FIG. 3 illustrates a cross-section of FIG. 2 taken along the sectional line AA′. For simplicity purpose and also to be consistent with the aforementioned embodiment, same elements in this embodiment and following embodiments are labeled with same numbering as previous embodiment and sectional lines are also omitted in the top view diagrams of the following embodiments. As shown in FIGS. 2-3, I contrast to the protection diode 18 in FIG. 1 only includes a doped region 46 and doped region 48, the protection diode 18 in this embodiment also includes a protection ring 54 consisting of doped regions 50, 52 surrounding the doped regions 46, 48, in which the doped regions 50, 52 and the lower doped region 46 preferably have same conductive type while the concentration of the doped region 50 is slightly lower than the concentration of the doped region 52 and the concentration of the doped region 52 is also lower than the concentration of the doped region 46. For instance, the doped region 50 preferably includes a PLDD region while the doped region 52 includes a p+ region. If comparing with the pickup region 16, the doped region 52 concentration is substantially equal to the doped region 44 concentration and the doped region 50 concentration is equal to the doped region 42 concentration.

Similar to the aforementioned embodiment, even though the protection ring 54 of this embodiment is consisting of two doped regions 50, 52, according to other embodiment of the present invention, the protection ring 54 could also be made of a single doped region such as a p+ region, which is also within the scope of the present invention. Moreover, as shown in FIG. 2, the doped region 48 in the protection diode 18 is electrically connected the gate structure 26 of the MOS transistor 14 through the contact plug 36 and metal interconnection 38.

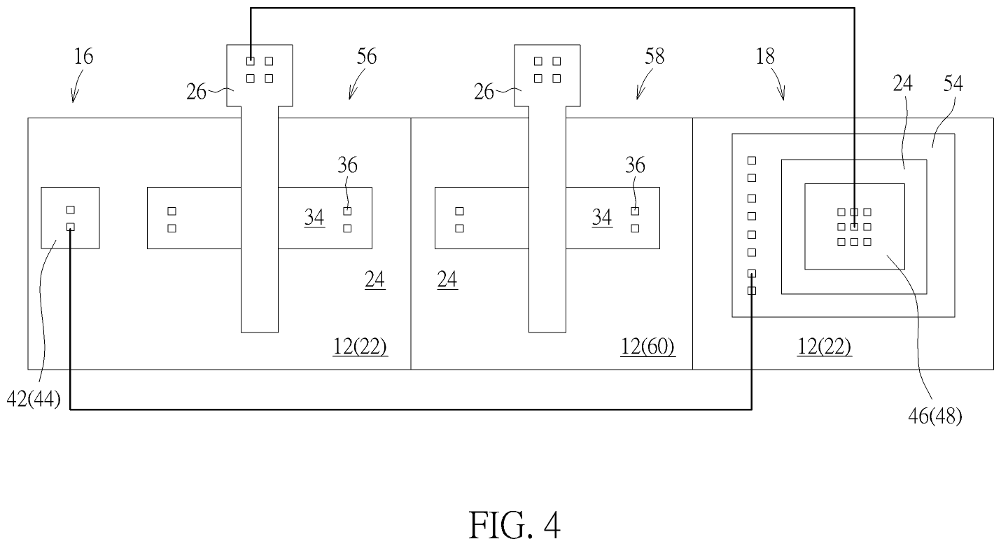

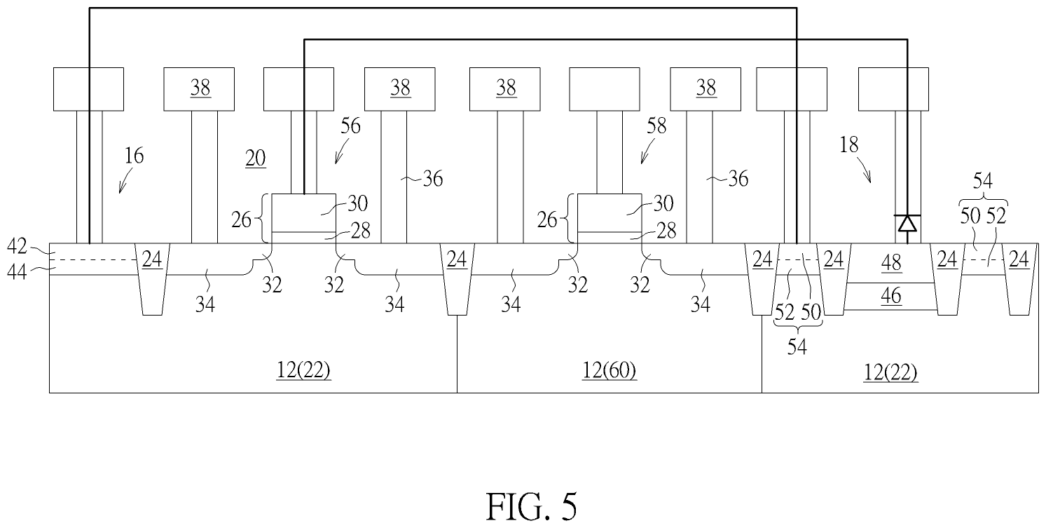

Referring to FIGS. 4-5, FIGS. 4-5 illustrate structural views of a semiconductor device according to an embodiment of the present invention, in which FIG. 4 illustrates a top view of the semiconductor device and FIG. 5 illustrates a cross-section of the semiconductor device shown in FIG. 4. As shown in FIGS. 4-5, in contrast to only a single MOS transistor 14 is disposed on the substrate 12 as shown in FIG. 1, a CMOS transistor is disposed between the pickup region 16 and the protection diode 18, in which the CMOS transistor includes a NMOS transistor 56 and a PMOS transistor 58 and the two transistors 56, 58 are separated by the STI 24.

Specifically, the LDD 32 of the NMOS transistor 56 includes a n-type LDD or NLDD, the source/drain region 34 of the NMOS transistor 56 includes a n+ region, and both the LDD 32 and the source/drain region 34 of the NMOS transistor 56 are disposed in the p-well 22. Similarly, the LDD 32 of the PMOS transistor 58 includes a p-type LDD or PLDD, the source/drain region 34 of the PMOS transistor 58 includes a p+ region, and both the LDD 32 and the source/drain region 34 of the PMOS transistor 58 are disposed in a n-well 60. The pickup region 16 and the protection diode 18 in this embodiment preferably have same structure as the pickup region 16 and protection diode 18 shown in FIG. 3. For instance, the pickup region 16 includes at least a doped region such as doped regions 42, 44, in which the doped region 42 on top includes p-type LDD or PLDD while the doped region 44 underneath includes a p+ region.

The protection diode 18 on right side of the NMOS transistor 56 and PMOS transistor 58 includes a protection ring 54 made of doped regions 50, 52 in addition to the doped regions 46, 48, in which the doped region 46 includes a p++ region, the doped region 48 includes a n++ region, the doped region 50 includes a PLDD, and the doped region 52 includes a p+ region. Similar to FIG. 4, the doped region 48 in the protection diode 18 is electrically connected to the gate structure 26 of the NMOS transistor 56 through the contact plug 36 and metal interconnection 38, and the protection ring 54 is electrically connected to the pickup region 16 through the contact plug 36 and metal interconnection 38.

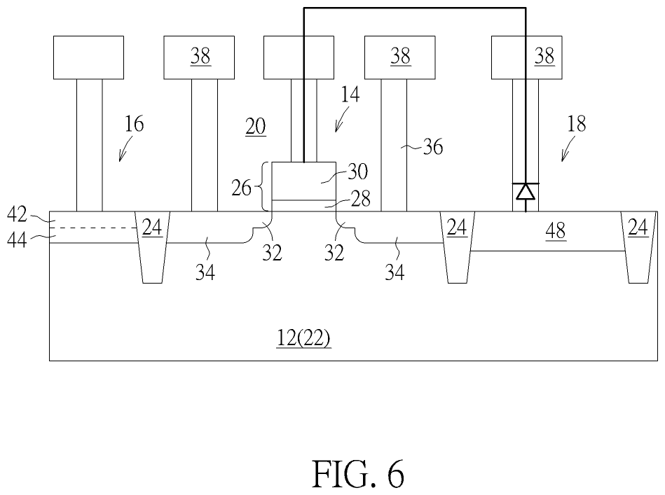

Referring to FIG. 6, FIG. 6 illustrates a structural view of a semiconductor device according to an embodiment of the present invention. As shown in FIG. 6, in contrast to the protection diode 18 in FIG. 1 includes two doped regions 46, 48, the protection diode 18 of this embodiment only includes a single doped region 48 disposed in the substrate 12, in which the doped region 48 includes a n++ region and the bottom surface of the doped region 48 could be slightly lower than the bottom surface of the source/drain 34 or the bottom surface of the doped region 44 in the pickup region 16.

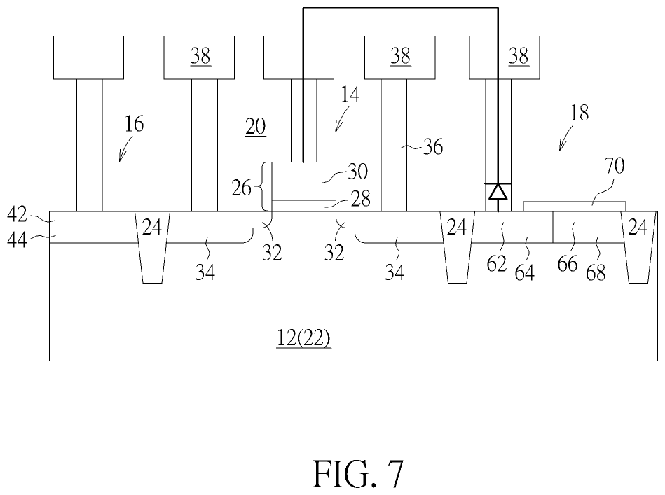

Referring to FIG. 7, FIG. 7 illustrates a structural view of a semiconductor device according to an embodiment of the present invention. As shown in FIG. 7, in contrast to the two doped regions 46, 48 in the protection diode in FIG. 1 are stacked one on top of another, the protection diode 18 of this embodiment includes two doped regions having different conductive type disposed one immediately adjacent to another. For instance, it would be desirable to dispose doped regions 62, 64 having n-type dopants on the left portion of the protection diode 18 and doped regions 66, 68 having p-type dopants on the right portion of the protection diode 18, in which doped region 62 on top left portion includes a NLDD having lower concentration while the doped region 64 underneath includes a n+ region having higher concentration. Similarly, the doped region 66 on top right portion includes a PLDD having lower concentration and the doped region 68 underneath includes a p+ region having higher concentration. Preferably, the bottom surface of the doped region 64 on the left could even with the bottom surface of the doped region 68 on the right.

It should be noted that the n-type doped regions 62, 64 on the left are electrically connected to the gate structures 26 through the contact plug 36 and metal interconnection 38 while a salicide block (SAB) 70 is disposed on top of the p-type doped regions 66, 68. In other words, silicides (not shown) could be formed on surface of the substrate 12 not covered by the SAB 70 including the doped region 42, the source/drain region 34, and the doped region 62 while no silicide is formed on the surface of the doped region 66. As a result, no contact plug or conductive wire is formed to directly contact the surface of the p-type doped region 66 as the surface of the doped region 66 is not exposed whatsoever.

Moreover, even though the n-type doped regions 62, 64 are disposed closer to the MOS transistor 14 while the p-type doped regions 66, 68 are disposed farther away from the MOS transistor 14, according to other embodiment of the present invention, it would also be desirable to exchange the left and right position of the doped regions 62, 64 with that of the doped regions 66, 68 while keeping the design of the n-type doped regions 62, 64 electrically connected to the contact plug 36 and the p-type doped regions 66, 68 are not connected to any contact plug, which is also within the scope of the present invention.

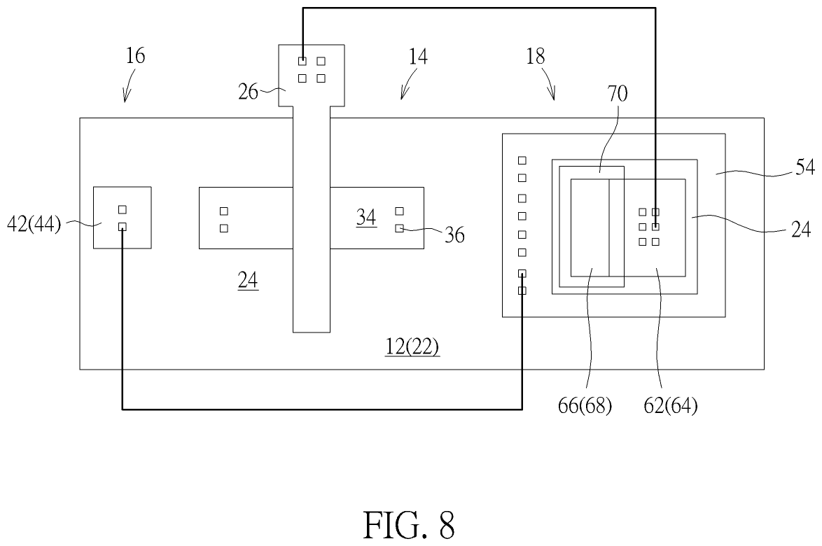

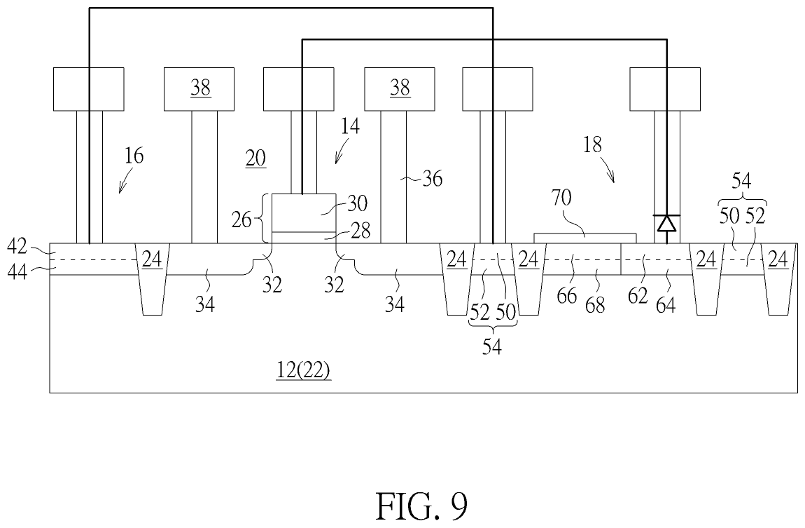

Referring to FIGS. 8-9, FIGS. 8-9 illustrate structural views of a semiconductor device according to an embodiment of the present invention, in which FIG. 8 illustrates a top view of the semiconductor device and FIG. 9 illustrates a cross-section of the semiconductor device shown in FIG. 8. As shown in FIGS. 8-9, it would be desirable to place the n-type doped regions 62, 64 connected to the gate structure 26 as shown FIG. 7 on the right side while the SAB 70 and the p-type doped regions 66, 68 underneath are disposed on the left side.

Moreover, the protection diode 18 includes a protection ring 54 made of doped regions 50, 52 surrounding the doped regions 62, 64, 66, 68. Similar to FIG. 4, the doped region 62 in the protection diode 18 is electrically connected to the gate structure 26 of the MOS transistor 14 through the contact plug 36 and metal interconnection 38 while the protection ring 54 is electrically connected to the pickup region 16 through the contact plug 36 and metal interconnection 38.

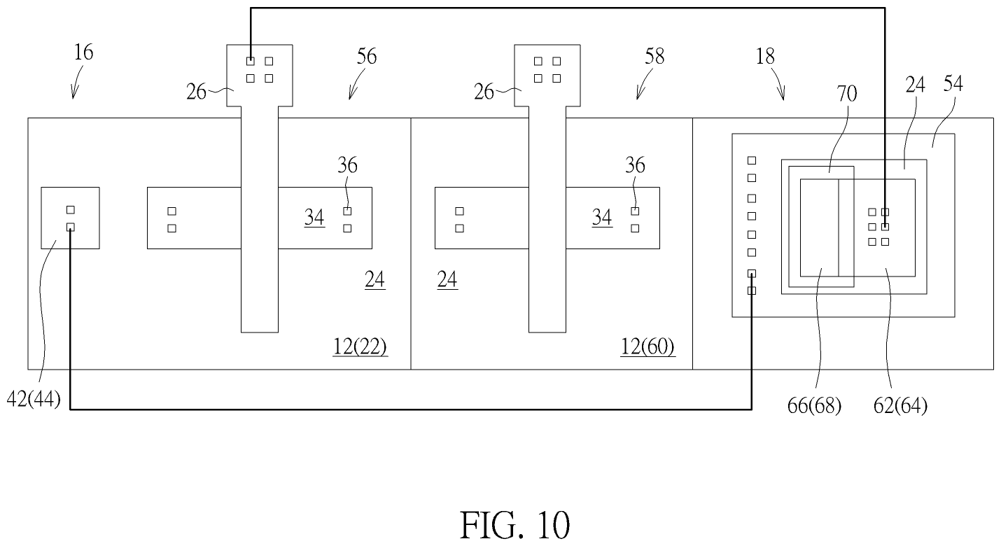

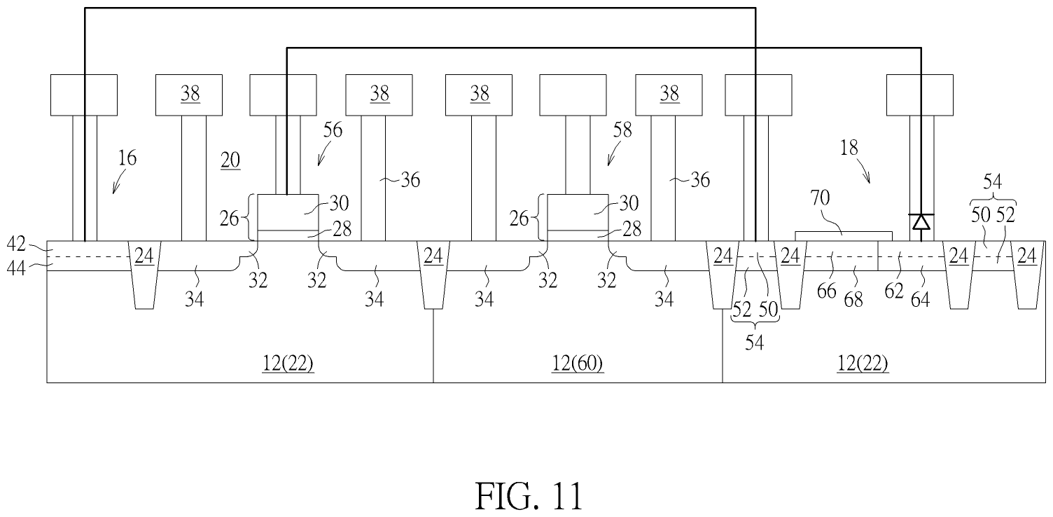

Referring to FIGS. 10-11, FIGS. 10-11 illustrate structural views of a semiconductor device according to an embodiment of the present invention, in which FIG. 10 illustrates a top view of the semiconductor device and FIG. 11 illustrates a cross-section of the semiconductor device shown in FIG. 10. As shown in FIGS. 10-11, it would be desirable to combine the CMOS transistor and the pickup region 16 shown in FIGS. 4-5 with the protection diode 18 shown in FIGS. 8-9 to form a new protection device.

For instance, in contrast to FIG. 8 only includes a single MOS transistor 14 on the substrate 12, it would be desirable to form a CMOS transistor between the pickup region 16 and the protection diode 18, in which the CMOS transistor includes a NMOS transistor 56 and a PMOS transistor 58 as the two transistors 56, 58 are separated by the STI 24.

Similar to the aforementioned embodiment, the LDD 32 of the NMOS transistor 56 includes a n-type LDD or NLDD, the source/drain region 34 of the NMOS transistor 56 includes a n+ region, and both the LDD 32 and the source/drain region 34 of the NMOS transistor 56 are disposed in the p-well 22. Similarly, the LDD 32 of the PMOS transistor 58 includes a p-type LDD or PLDD, the source/drain region 34 of the PMOS transistor 58 includes a p+ region, and both the LDD 32 and the source/drain region 34 of the PMOS transistor 58 are disposed in a n-well 60. The pickup region 16 in this embodiment preferably has same structure as the pickup region 16 shown in FIG. 5. For instance, the pickup region 16 includes at least a doped region such as doped regions 42, 44, in which the doped region 42 on top includes a p-type LDD or PLDD while the doped region 44 underneath includes a p+ region.

Similar to FIG. 7 or FIG. 9, the protection diode 18 of this embodiment places the n-type doped regions 62, 64 on the right side while the SAB 70 and the p-type doped regions 66, 68 underneath are disposed on the left side. The protection diode 18 further includes a protection ring 54 made of doped regions 50, 52 surrounding the doped regions 62, 64, 66, 68, in which the doped region 62 is electrically connected to the gate structure 26 of the MOS transistor 14 through the contact plug 36 and metal interconnection 38 while the protection ring 54 is electrically connected to the pickup region 16 through the contact plug 36 and metal interconnection 38.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. A semiconductor device, comprising:
a first metal-oxide semiconductor (MOS) transistor on a substrate;
a pickup region adjacent to one side of the first MOS transistor; and
a protection diode adjacent to another side of the first MOS transistor, wherein the pickup region and the protection diode comprise different conductive type.

2. The semiconductor device of claim 1, wherein the first MOS transistor comprises:
a first gate structure on the substrate; and
a first source/drain region adjacent to two sides of the first gate structure.

3. The semiconductor device of claim 2, wherein the protection diode is electrically connected to the first gate structure.

4. The semiconductor device of claim 2, wherein the pickup region comprises a first conductive type.

5. The semiconductor device of claim 4, wherein the protection diode comprises:
a first doped region in the substrate, wherein the first doped region comprises the first conductive type; and
a second doped region on the first doped region, wherein the second doped region comprises a second conductive type.

6. The semiconductor device of claim 5, wherein a concentration of the pickup region is less than a concentration of the first doped region.

7. The semiconductor device of claim 4, wherein the protection diode comprises:
a well region in the substrate, wherein the well region comprises the first conductive type; and
a doped region on the well region, wherein the doped region comprises a second conductive type.

8. The semiconductor device of claim 7, wherein a concentration of the well region is less than a concentration of the pickup region.

9. The semiconductor device of claim 4, wherein the protection diode comprises:
a first doped region in the substrate, wherein the first doped region comprises the first conductive type; and
a second doped region adjacent to the first doped region, wherein the second doped region comprises a second conductive type.

10. The semiconductor device of claim 9, wherein the second doped region is electrically connected to the first gate structure.

11. The semiconductor device of claim 9, wherein bottom surfaces of the first doped region and the second doped region are coplanar.

12. The semiconductor device of claim 9, further comprising a salicide block (SAB) on the first doped region.

13. The semiconductor device of claim 1, further comprising a second MOS transistor between the first MOS transistor and the protection diode.

14. The semiconductor device of claim 13, wherein the first MOS transistor and the second MOS transistor comprise different conductive type.

15. The semiconductor device of claim 13, wherein the second MOS transistor comprises:
a second gate structure on the substrate; and
a second source/drain region adjacent to two sides of the second gate structure.
